(19) United States
(12) Patent Application Publication
(10) Pub. No.: US 2020/0088828 A1
(43) Pub. Date: Mar. 19, 2020

(54) WAFER TESTING APPARATUS AND METHOD OF DIAGNOSING WAFER TESTING APPARATUS

(71) Applicant: Tokyo Electron Limited, Tokyo (JP)

(72) Inventor: Shinya KUREBAYASHI, Yamanashi (JP)

(21) Appl. No.: 16/494,336

(22) PCT Filed: Mar. 8, 2018
(86) PCT No.: PCT/JP2018/009012

§ 371 Date: Sep. 16, 2019

(30) Foreign Application Priority Data
Mar. 22, 2017 (JP) 2017-056523

(51) Int. Cl. G01R 35/00; G01R 31/28; G01R 1/073

(52) U.S. Cl. CPC G01R 35/00; G01R 1/07342; G01R 31/2889

(57) ABSTRACT

A wafer testing apparatus according to an embodiment includes a tester configured to apply electrical signals to a semiconductor device fabricated on a wafer, a prober configured to cause the semiconductor device to be electrically coupled to the tester, a tester controller configured to control an operation of the tester, and a prober controller configured to control an operation of the prober, wherein the tester controller and the prober controller communicate with each other when diagnosing a state of the tester.

### TECHNICAL FIELD

The present invention relates to a wafer testing apparatus and a method of diagnosing a wafer testing apparatus.

### BACKGROUND ART

Wafer testing apparatuses are conventionally known that include a tester for applying electrical signals to semiconductor devices fabricated on a wafer and a prober for electrically coupling the semiconductor devices to the tester through a probe card.

In such wafer testing apparatuses, a diagnostic board, in place of a probe card, is attached to the test head at the time of powering on an apparatus or after maintenance work, thereby diagnosing whether the tester is in normal conditions.

### RELATED-ART DOCUMENTS

### Patent Document

[Patent Document 1] Japanese Patent Application Publication No. 2005-308587

### SUMMARY OF THE INVENTION

### Problem to be Solved by the Invention

In the case of attaching a diagnostic board to perform diagnosis, an operator or the like needs to operate a tester and a prober alternately, such as operating the tester to select a diagnostic mode and operating the prober to attach a diagnostic board to the test head. As a result, the problem arises that laborious process and lengthy steps are involved, and operation errors may also occur.

In consideration of the above, it is an object of the present invention to provide a wafer testing apparatus capable of reducing laborious process and lengthy steps so as to prevent operation errors.

### Means to Solve the Problem

In order to achieve the above-noted object, a wafer testing apparatus according to an embodiment of the present invention includes a tester configured to apply electrical signals to a semiconductor device fabricated on a wafer, a prober configured to cause the semiconductor device to be electrically coupled to the tester, a tester controller configured to control an operation of the tester, and a prober controller configured to control an operation of the prober, wherein the tester controller and the prober controller communicate with each other when diagnosing a state of the tester.

### Advantage of the Invention

According to the disclosed wafer testing apparatus, laborious process and lengthy steps are reduced, and operation errors are prevented.

### BRIEF DESCRIPTION OF DRAWINGS

FIG. 1 is a schematic cross-sectional view illustrating an example of a wafer testing apparatus according to an embodiment of the present invention.

FIG. 2 is a cross-sectional view taken along the dot-and-dash line A-A in FIG. 1.

FIG. 3 is a drawing for illustrating a tester controller and a prober controller in the wafer testing apparatus.

FIG. 4 is a sequence diagram illustrating the flow of a diagnostic process according to the embodiment of the present invention.

FIG. 5 is a flowchart illustrating the operations of the tester in the diagnostic process.

FIG. 6 is a flowchart illustrating the operations of the prober in the diagnostic process.

FIG. 7 is a sequence diagram illustrating the flow of a probe card exchange process according to the embodiment of the present invention.

FIG. 8 is a flowchart illustrating the operations of the tester in the probe card exchange process.

FIG. 9 is a flowchart illustrating the operations of the prober in the probe card exchange process.

### MODE FOR CARRYING OUT THE INVENTION

In the following, embodiments for carrying out the invention will be described by referring to the accompanying drawings. In the specification and drawings, elements having substantially the same configurations are referred to by the same numerals, and a duplicate description thereof will be omitted.

### Wafer Testing Apparatus

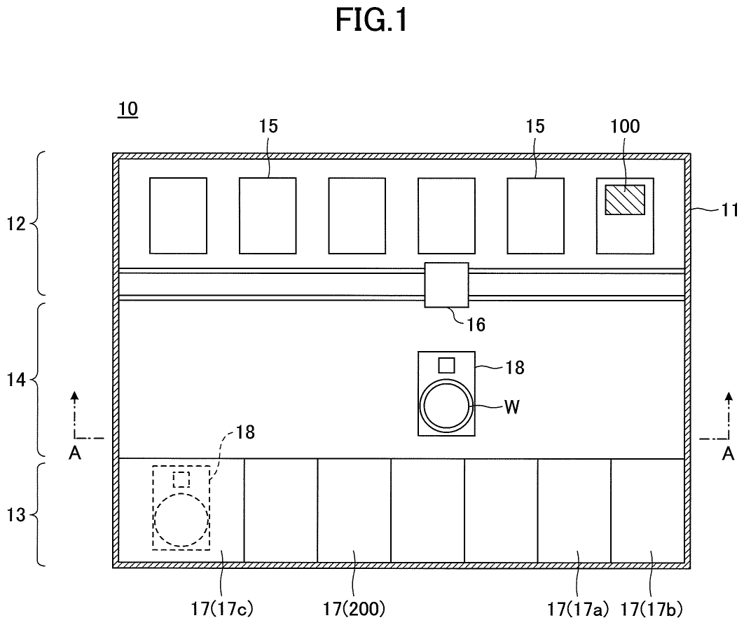

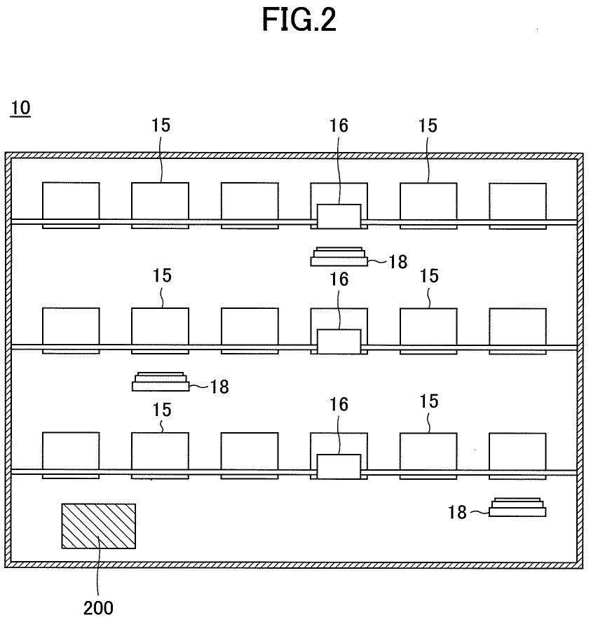

A wafer testing apparatus according to an embodiment of the present invention will be described. FIG. 1 is a schematic cross-sectional view illustrating an example of a wafer testing apparatus according to the embodiment of the present invention. FIG. 2 is a cross-sectional view taken along the dot-and-dash line A-A in FIG. 1.

As illustrated in FIG. 1 and FIG. 2, a wafer testing apparatus 10 includes a test chamber 11. The test chamber 11 includes a test area 12 for testing the electrical characteristics of semiconductor devices fabricated on a wafer W, a load-and-unload area 13 for loading and unloading the wafer W to and from the test chamber 11, and a transfer area 14 disposed between the test area 12 and the load-and-unload area 13.

Testers 15 are provided in the test area 12 as an interface for testing a plurality of wafers. Specifically, the test area 12 has a multistage structure, e.g., a three-stage structure, having tester arrays each comprised of a plurality of testers 15 arranged horizontally. A single tester side camera 16 is disposed for each of the tester arrays. Each tester side camera 16, which moves horizontally along a corresponding tester array, stops in front of a tester 15 constituting the tester array to check the position of a wafer W or the like transported by a transport stage 18, which will be described later. A tester controller 100 for controlling the operation of the tester 15 is disposed in the test area 12.

The load-and-unload area 13 is divided into a plurality of storage spaces 17. The storage spaces 17 include a port 17a for receiving FOUP, which is a container for storing a plurality of wafers W, an aligner 17b for aligning wafers W, and a loader 17c for loading and unloading a probe card, a diagnostic board, and the like. A probe card, which is employed to test the electrical characteristics of semiconductor devices fabricated on a wafer W, is a tool that electrically connects the electrodes of the semiconductor devices to the tester. A diagnostic board is a tool in which circuits for diagnosing the tester 15 are placed. A diagnostic board may alternatively be loaded from a dedicated port (not shown) that is different from the loader 17c. The storage spaces 17 also house a prober controller 200 for controlling the operation of a prober 21 which includes the port 17a, the aligner 17b, the loader 17c, the transport stage 18, and the like.

The transfer area 14 houses the transport stage 18, which is movable not only in the transfer area 14 but also movable to the test area 12 and to the load-and-unload area 13. The transport stage 18 receives a wafer W from the port 17a of the load-and-unload area 13 for transport to a tester 15, and also transport a wafer W from a tester 15 to the port 17a after the testing of electrical characteristics of the semiconductor devices is completed. The transport stage 18 receives a probe card required for a test from the loader 17c of the load-and-unload area 13 for transport to a tester 15, and transports a probe card not required for a test from a tester 15 to the loader 17c. The transport stage 18 receives a diagnostic card required for diagnosis from the loader 17c or the dedicated port of the load-and-unload area 13 for transport to a tester 15, and transports a diagnostic card not required for diagnosis from a tester 15 to the loader 17c or to the dedicated port. Transport of a probe card and/or a diagnostic board may be performed by a transport device separate from the transport stage 18.

In such a wafer testing apparatus 10, each tester 15 applies electrical signals to semiconductor devices on a wafer W to test electrical characteristics. In so doing, while the transport stage 18 carries a wafer W toward a given tester 15, another tester 15 may test the electrical characteristics of semiconductor devices on another wafer W. This improves the efficiency of testing wafers W.

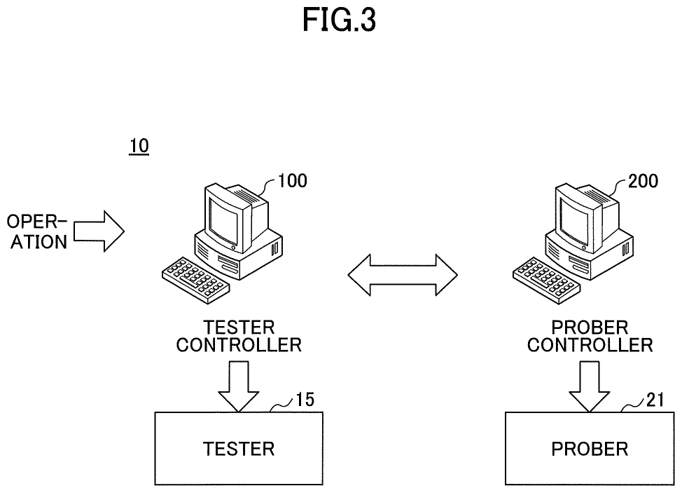

In the following, the tester controller 100 and the prober controller 200 of the wafer testing apparatus 10 will be described. FIG. 3 is a drawing illustrating the tester controller 100 and the prober controller 200 of the wafer testing apparatus 10 illustrated in FIG. 1.

As illustrated in FIG. 3, the wafer testing apparatus 10 includes a tester 15 and a prober 21. The operation of the tester 15 and the operation of the prober 21 are controlled by the tester controller 100 and the prober controller 200, respectively.

Upon receiving operational input for starting a diagnostic process to diagnose the state of the tester 15, e.g., to determine whether the tester 15 is operating normally, the tester controller 100 communicates with the prober controller 200 to automatically execute the diagnostic process. Further, upon receiving operational input for selecting the content of test for a device to be tested (DUT: device under test) and for starting the test, the tester controller 100 communicates with the prober controller 200 to automatically execute a probe-card exchange process. The details of the diagnostic process and the probe-card exchange process will be described later.

In this manner, the wafer testing apparatus 10 according to the embodiment of the present invention allows the tester controller 100 and the prober controller 200 to communicate with each other to perform a diagnostic process and/or a probe-card exchange process. With this arrangement, laborious process and lengthy steps for a diagnostic process and/or a probe-card exchange process are reduced, which serves to prevent operation errors.

### Diagnostic Process

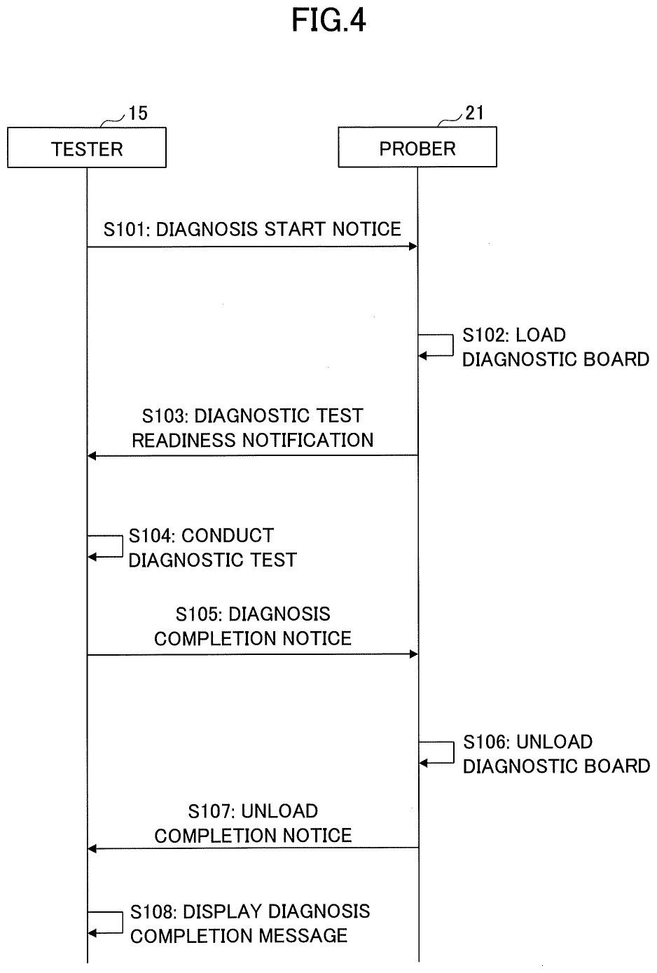

In the following, a diagnostic process (a diagnostic method) by the wafer testing apparatus 10 according to the embodiment of the present invention will be described with reference to FIG. 4. FIG. 4 is a sequence diagram illustrating the flow of a diagnostic process according to the embodiment of the present invention. In FIG. 4, the solid arrows indicate communications between the tester controller 100 and the prober controller 200.

The diagnostic process is a process which diagnoses the state of a tester 15 by attaching a diagnostic board to the test head of the tester 15 in place of a probe card at the time of powering on, or after maintenance of, the device, for example.

Upon receiving operational input for selecting the content of a diagnostic test and for starting the test from an operator or the like, the wafer testing apparatus 10 executes a diagnostic process. The diagnostic process by the wafer testing apparatus 10 is automatically performed based on communications between the tester controller 100 and the prober controller 200.

First, upon receiving operational input for selecting the content of a diagnostic test and for starting the test, the tester 15 transmits a diagnosis start notice to the prober 21 in step S101. The diagnosis start notice may include an indication of the selected content of a diagnostic test, for example.

Upon receiving operational input for starting the diagnostic test of step S101, the prober 21 loads a diagnostic board corresponding to the diagnostic test content to the tester 15 in step S102. Thereafter, in step S103, the prober 21 transmits a diagnostic test readiness notification to the tester 15. The diagnostic test readiness notification may include the result of determination as to whether the diagnostic test by use of the tester 15 is executable.

Upon receiving the diagnostic test readiness notification in step S103, the tester 15 conducts the diagnostic test in step S104. Thereafter, in step S105, the tester 15 transmits a diagnosis completion notice to the prober 21. The diagnosis completion notice may include an indication of whether the diagnostic test has been executed and the results of diagnosis in the case of the diagnostic test being executed.

Upon receiving the diagnosis completion notice of step S105, the prober 21 unloads the diagnostic board from the tester 15 in step S106. Thereafter, in step S107, the prober 21 transmits an unload completion notice to the tester 15.

Upon receiving the unload completion notice of step S107, the tester 15 displays a message indicative of the completion of diagnosis in step S108, followed by bringing the diagnostic process to an end.

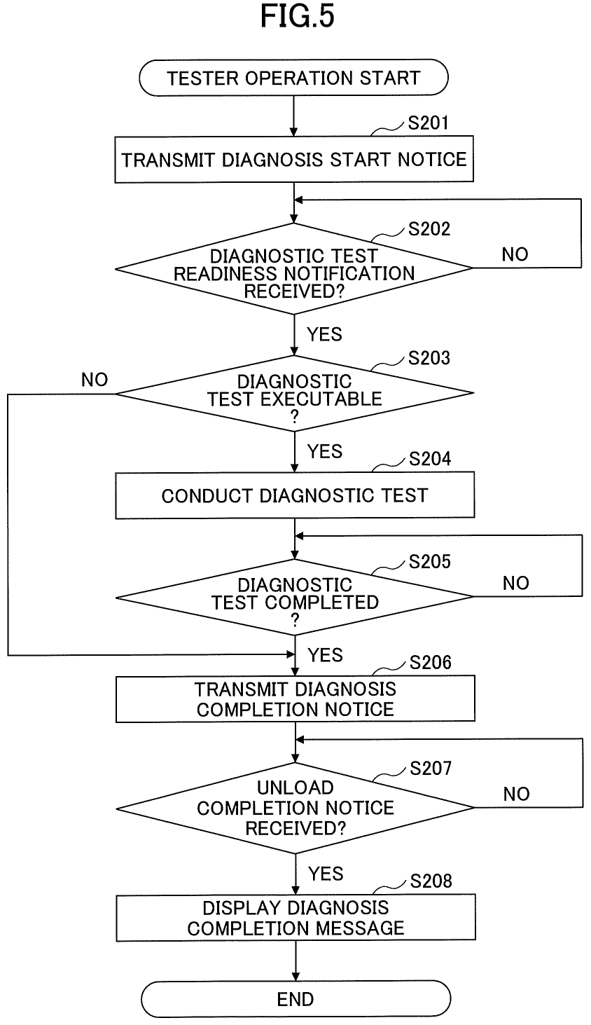

In the following, the details of operations of the tester 15 to actualize the above-described operation will be described with reference to FIG. 5. FIG. 5 is a flowchart illustrating the operations of the tester 15 in the diagnostic process. The processes illustrated in this flowchart are actualized by the tester controller 100 controlling the individual parts of the tester 15 in accordance with input signals, programs, and the like. The tester controller 100 starts the flowchart illustrated in FIG. 5 upon determining that operational input for selecting the content of a diagnostic test and for starting a diagnostic test is received from an operator or the like.

In step S201, the tester controller 100 transmits a diagnosis start notice to the prober controller 200. The diagnosis start notice may include an indication of the selected content of a diagnostic test, for example. This process corresponds to step S101 in FIG. 4.

In step S202, the tester controller 100 determines whether a diagnostic test readiness notification is received from the prober controller 200. The diagnostic test readiness notification may include the result of determination as to whether the diagnostic test by use of the tester 15 is executable. Upon determining that a diagnostic test readiness notification is received, the tester controller 100 proceeds to step S203. Upon determining that a diagnostic test readiness notification is not received, the tester controller 100 performs step S202 again.

In step S203, the tester controller 100 checks whether the diagnostic test can be conducted based on the diagnostic test readiness notification received in step S202. Upon determining that the diagnostic test can be conducted, the tester controller 100 proceeds to step S204. Upon determining that the diagnostic test cannot be conducted, on the other hand, the tester controller 100 proceeds to step S206.

In step S204, the tester controller 100 conducts the diagnostic test of such content indicated in step S201. This process corresponds to step S104 in FIG. 4.

In step S205, the tester controller 100 checks whether the diagnostic test executed in step S204 is completed. Upon determining that the diagnostic test is completed, the tester controller 100 proceeds to step S206. Upon determining that the diagnostic test is not completed, on the other hand, the tester controller 100 performs step S205 again.

In step S206, the tester controller 100 transmits a diagnosis completion notice to the prober controller 200. The diagnosis completion notice may include an indication of whether the diagnostic test has been executed and the results of diagnosis in the case of the diagnostic test being executed. This process corresponds to step S105 in FIG. 4.

In step S207, the tester controller 100 determines whether an unload completion notice is received from the prober controller 200. Upon determining that the unload completion notice is received, the tester controller 100 proceeds to step S208. Upon determining that the unload completion notice is not received, on the other hand, the tester controller 100 performs step S207 again.

In step S208, the tester controller 100 displays an indication that the diagnosis has been completed, which marks the end of this flowchart. This process corresponds to step S108 in FIG. 4.

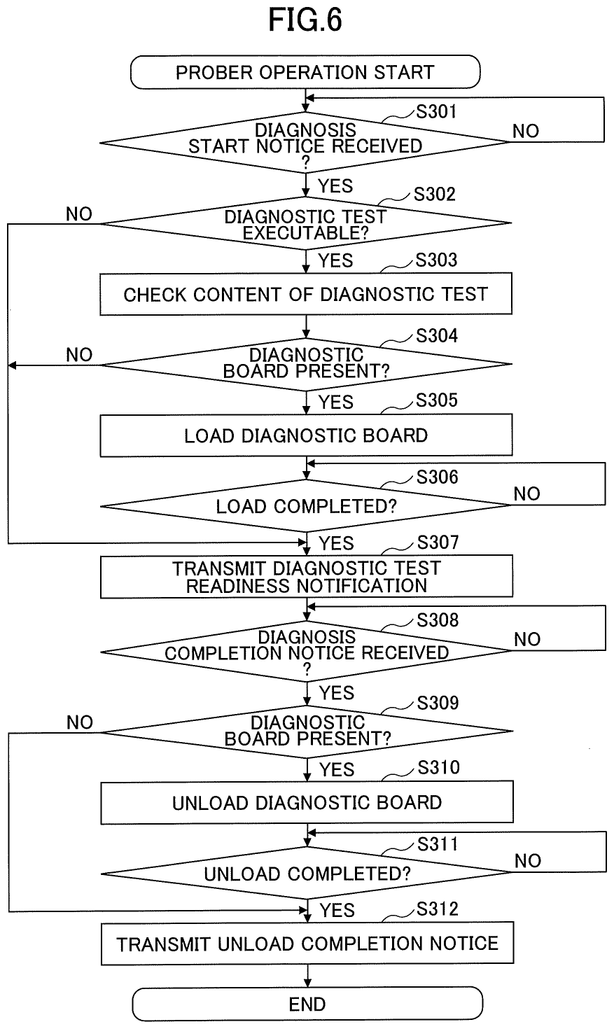

In the following, the details of operations of the prober 21 to actualize the above-described operation will be described with reference to FIG. 6. FIG. 6 is a flowchart illustrating the operations of the prober in the diagnostic process. The processes illustrated in this flowchart are actualized by the prober controller 200 controlling the individual parts of the prober 21 in accordance with input signals, programs, and the like.

In step S301, the prober controller 200 determines whether a diagnosis start notice is received from the tester controller 100. Upon determining that a diagnosis start notice is received, the prober controller 200 proceeds to step S302. Upon determining that a diagnosis start notice is not received, on the other hand, the prober controller 200 performs step S301 again.

In step S302, the prober controller 200 checks the load status of a probe card or the like with respect to the tester 15 to determine whether the diagnostic test can be conducted by the tester 15.

Upon determining that the diagnostic test can be conducted, the prober controller 200 proceeds to step S303. Upon determining that the diagnostic test cannot be conducted, on the other hand, the prober controller 200 proceeds to step S307. Specifically, the prober controller 200 unloads a probe card from the tester 15 when the probe card has been loaded in the tester 15 and can be unloaded, followed by determining that a diagnostic test is executable. When the tester 15 has no probe card loaded thereto, the prober controller 200 determines that a diagnostic test is executable. When a probe card has been loaded in the tester 15 and cannot be unloaded, or when the tester 15 cannot conduct a self-diagnosis for other reasons, the prober controller 200 determines that a diagnostic test is not executable.

In step S303, the prober controller 200 checks the content of a diagnostic test based on the diagnosis start notice received in step S301.

In step S304, the prober controller 200 determines whether there is a diagnostic board corresponding to the content of a diagnostic test checked in step S303. Upon determining that the diagnostic board is present, the prober controller 200 proceeds to step S305. Upon determining that the diagnostic board is not present, on the other hand, the prober controller 200 proceeds to step S307. It may be noted that, when the content of a diagnostic test checked in step S303 does not involve the use of a diagnostic board, the procedure proceeds to step S305.

In step S305, the prober controller 200 loads the diagnostic board corresponding to the content of a diagnostic test to the tester 15. It may be noted that, when the content of a diagnostic test checked in step S303 does not involve the use of a diagnostic board, no diagnostic bard is loaded to the tester 15. This process corresponds to step S102 in FIG. 4.

In step S306, the prober controller 200 checks whether loading the diagnostic board to the tester is completed. Upon determining that the loading the diagnostic board to the tester 15 is completed, the prober controller 200 proceeds to step S307. Upon determining that loading the diagnostic board to the tester 15 is not completed, on the other hand, the prober controller 200 performs step S306 again.

In step S307, the prober controller 200 transmits a diagnostic test readiness notification to the tester controller 100. The diagnostic test readiness notification may include the result of determination as to whether the diagnostic test by use of the tester 15 is executable. This process corresponds to step S103 in FIG. 4.

In step S308, the prober controller 200 determines whether a diagnosis completion notice is received from the tester controller 100. Upon determining that a diagnosis completion notice is received, the prober controller 200 proceeds to step S309. Upon determining that a diagnosis completion notice is not received, on the other hand, the prober controller 200 performs step S308 again.

In step S309, the prober controller 200 checks whether the diagnostic board is present on the tester 15. Upon determining that the diagnostic board is present on the tester 15, the prober controller 200 proceeds to step S310. Upon determining that the diagnostic board is not present on the tester 15, on the other hand, the prober controller 200 proceeds to step S312.

In step S310, the prober controller 200 unloads the diagnostic board from the tester 15. This process corresponds to step S106 in FIG. 4.

In step S311, the prober controller 200 checks whether unloading the diagnostic board is completed. Upon determining that unloading the diagnostic board is completed, the prober controller 200 proceeds to step S312. Upon determining that unloading the diagnostic board is not completed, on the other hand, the prober controller 200 performs step S311 again.

In step S312, the prober controller 200 transmits an unload completion notice to the tester controller 100, which marks the end of this flowchart. This process corresponds to step S107 in FIG. 4.

As described above, the wafer testing apparatus according to the embodiment of the present invention causes a series of diagnostic process steps to be automatically performed while the tester controller 100 and the prober controller 200 communicate with each other. This brings about the following advantages.

The tester controller 100 and the prober controller 200 automatically determine and execute a series of operations, which improves the overall operability of the wafer testing apparatus 10, and reduces the operating steps performed by the operator or the like.

Further, the operator or the like can execute a diagnostic process with respect to the wafer testing apparatus 10 by performing only one operation on one of the controllers, which eliminates the need to operate the tester controller 100 and the prober controller 200 alternately, thereby shortening the time required for diagnosis.

In addition, the tester controller 100 and the prober controller 200 automatically determine and execute a process according to the content of a diagnostic test selected by the operator or the like, which serves to prevent human operation errors by the operator or the like. It follows that the destruction of the tester 15 and the prober 21 and damage to the wafers W caused by erroneous operations are less likely to occur.

Moreover, the tester controller 100 and the prober controller 200 operate in collaboration with each other, thereby allowing these controllers to evaluate whether a probe card and/or a diagnostic board are loaded to the tester 15, thereby preventing erroneous operations from being performed while the diagnostic test is not executable.

### Probe Card Exchange Process

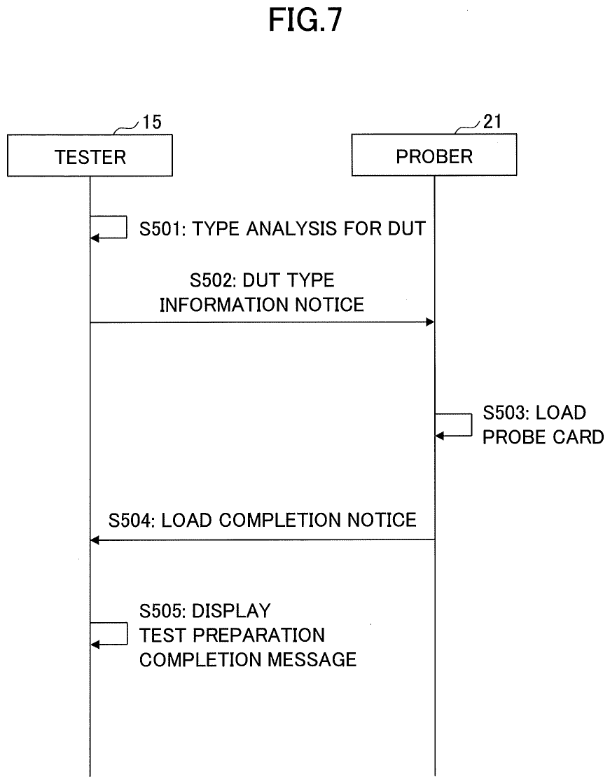

In the following, a probe card exchange process by the wafer testing apparatus 10 according to the embodiment of the present invention will be described with reference to FIG. 7. FIG. 7 is a sequence diagram illustrating the flow of a probe card exchange process according to the embodiment of the present invention. In FIG. 7, the solid arrows indicate communications between the tester controller 100 and the prober controller 200.

The probe card exchange process is performed when the content of a test is changed due to a change in the DUT, for example. Upon receiving operational input for selecting the content of a test and for starting the test from an operator or the like, the wafer testing apparatus 10 executes a probe card exchange process. The probe card exchange process by the wafer testing apparatus 10 is automatically performed based on communications between the tester controller 100 and the prober controller 200.

First, upon receiving operational input for selecting the content of a test and for starting the test, the tester 15 performs a type analysis with respect to the DUT in step S501. Thereafter, in step S502, the tester 15 transmits a DUT type information notice to the prober 21. The DUT type information notice may include information indicative of a type of probe card required for the selected test content, for example.

Upon receiving the DUT type information notice of step S502, the prober 21 loads a probe card corresponding to the subject matter of the type to the tester 15 in step S503. Thereafter, in step S504, the prober 21 transmits a load completion notice to the tester 15. The load completion notice may include information indicative of whether the probe card required for the selected test content has been loaded to the tester 15, for example.

Upon receiving the load completion notice of step S504, the tester 15 displays a message indicative of the completion of test preparation in step S505, followed by bringing the probe card exchange process to an end.

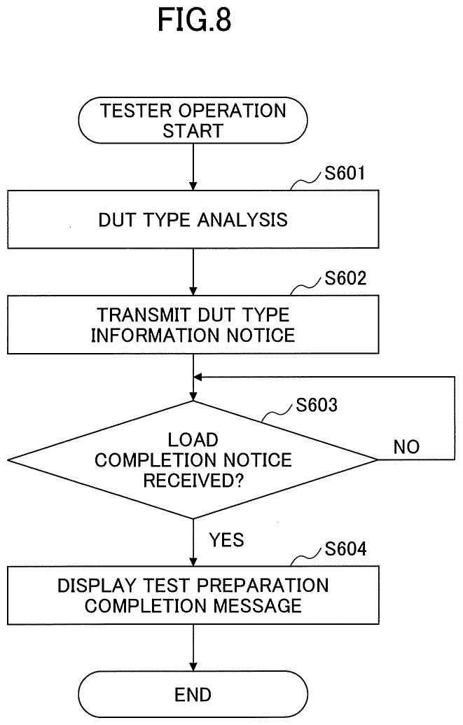

In the following, the details of operations of the tester 15 to actualize the above-described operation will be described with reference to FIG. 8. FIG. 8 is a flowchart illustrating the operations of the tester 15 in the probe card exchange process. The processes illustrated in this flowchart are actualized by the tester controller 100 controlling the individual parts of the tester 15 in accordance with input signals, programs, and the like. The tester controller 100 starts the flowchart illustrated in FIG. 8 upon determining that operational input for selecting the content of a test and for starting a test is received from an operator or the like.

In step S601, the tester controller 100 performs a type analysis with respect to the DUT. Specifically, the tester controller 100 identifies the type of probe card required for the test based on the selected test content. This process corresponds to step S501 in FIG. 7.

In step S602, the tester controller 100 transmits a DUT type information notice to the prober controller 200. The DUT type information notice may include information indicative of a type of probe card required for the selected test content, for example. This process corresponds to step S502 in FIG. 7.

In step S603, the tester controller 100 determines whether a load completion notice is received from the prober controller 200. Upon determining that a load completion notice is received, the tester controller 100 proceeds to step S604. Upon determining that a load completion notice is not received, the tester controller 100 performs step S603 again.

In step S604, the tester controller 100 displays a message indicative of the completion of preparation for a DUT test or a message indicative of the absence of a probe card required for the DUT test, which marks the end of the flowchart. This process corresponds to step S505 in FIG. 7.

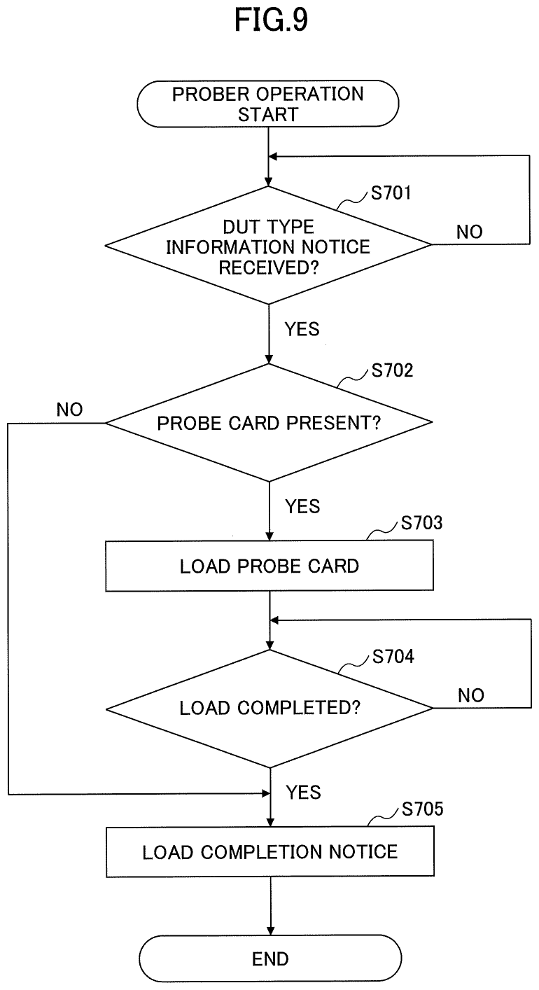

In the following, the details of operations of the prober 21 to actualize the above-described operation will be described with reference to FIG. 9. FIG. 9 is a flowchart illustrating the operations of the prober in the probe card exchange process. The processes illustrated in this flowchart are actualized by the prober controller 200 controlling the individual parts of the prober 21 in accordance with input signals, programs, and the like.

In step S701, the prober controller 200 determines whether a DUT type information notice is received from the tester controller 100. Upon determining that a DUT type information notice is received, the prober controller 200 proceeds to step S702. Upon determining that a DUT type information notice is not received, on the other hand, the prober controller 200 performs step S701 again.

In step S702, the prober controller 200 checks, based on the DUT type information notice, whether there is a probe card required for the selected test content. Upon determining that the probe card required for the selected test content is present, the prober controller 200 proceeds to step S703. Upon determining that the probe card required for the selected test content is not present, on the other hand, the prober controller 200 proceeds to step S705.

In step S703, the prober controller 200 loads the probe card required for the selected test content to the tester 15. This process corresponds to step S503 in FIG. 7.

In step S704, the prober controller 200 checks whether loading the probe card to the tester 15 is completed. Upon determining that the loading the probe card to the tester 15 is completed, the prober controller 200 proceeds to step S705. Upon determining that loading the probe card to the tester 15 is not completed, on the other hand, the prober controller 200 performs step S704 again.

In step S705, the prober controller 200 transmits a load completion notice to the tester controller 100, which marks the end of this flowchart. The load completion notice may include information indicative of whether the probe card required for the selected test content has been loaded to the tester 15, for example. This process corresponds to step S504 in FIG. 7.

As described above, the wafer testing apparatus according to the embodiment of the present invention causes a series of probe card exchange process steps to be automatically performed while the tester controller 100 and the prober controller 200 communicate with each other. This brings about the following advantages.

The tester controller 100 and the prober controller 200 automatically determine and execute a series of operations, which improves the overall operability of the wafer testing apparatus 10, and reduces the operating steps performed by the operator or the like.

Further, the operator or the like can execute a probe card exchange process with respect to the wafer testing apparatus 10 by performing only one operation on one of the controllers, which eliminates the need to operate the tester controller 100 and the prober controller 200 alternately, thereby shortening the time required for exchanging probe cards.

In addition, the tester controller 100 and the prober controller 200 automatically determine and execute a process according to the content of a test selected by the operator or the like, which serves to prevent human operation errors, such as an error in selecting a probe card, made by the operator or the like. It follows that the destruction of the tester 15 and the prober 21 and damage to the wafers W caused by erroneous operations are less likely to occur.

Although the one or more embodiments of the present invention have heretofore been described, what have been described is not intended to limit the subject matter of the invention. Various modifications and improvements may be made within the scope of the present invention.

With respect to the above-described embodiment, a description has been directed to an example in which a diagnostic process is started when the tester controller 100 receives operational input for performing a diagnostic process. Notwithstanding this, the present invention is not limited to such an example. For example, a diagnostic process may be started when the prober controller 200 receives operational input for performing a diagnostic process. In this case, step S101 illustrated in FIG. 4 can be omitted.

With respect to the above-described embodiment, a description has been directed to an example in which a probe card exchange process is started when the tester controller 100 receives operational input for performing a probe card exchange process. Notwithstanding this, the present invention is not limited to such an example. For example, a probe card exchange process may be started when the prober controller 200 receives operational input for performing a probe card exchange process. In this case, it suffices for the prober controller 200 to perform a type analysis with respect to the DUT (step S501) in FIG. 7. Further, step S502 can be omitted.

Further, a control apparatus such as a higher-level controller capable of communicating with the tester controller 100 and the prober controller 200 may be provided at a higher level than those controllers. In this case, an operator or the like may operate the control apparatus to cause the tester controller 100 and the prober controller 200 to perform the diagnostic process and the probe card exchange process previously described. Also, the control apparatus may be installed at a location different from where the wafer testing apparatus 10 is installed, for example, so that the operator or the like may remotely perform a diagnostic process and a probe card exchange process.

This international patent application claims priority to Japanese Patent Application No. 2017-056523 filed on Mar. 22, 2017, the entire contents of which are incorporated herein by reference.

### Description of Reference Symbols

15 Tester
21 Prober
100 Tester Control Unit
200 Prober Control Unit
W Wafer

1. A wafer testing apparatus, comprising:
a tester configured to apply electrical signals to a semiconductor device fabricated on a wafer;
a prober configured to cause the semiconductor device to be electrically coupled to the tester;
a tester controller configured to control an operation of the tester; and
a prober controller configured to control an operation of the prober,
wherein the tester controller and the prober controller communicate with each other when performing a diagnostic process for diagnosing a state of the tester.

2. The wafer testing apparatus as claimed in claim 1, wherein the tester controller and the prober controller perform the diagnostic process when one of the tester controller and the prober controller receives operational input for starting the diagnostic process.

3. The wafer testing apparatus as claimed in claim 1, further comprising a control apparatus configured to communicate with the tester controller and the prober controller,
wherein the tester controller and the prober controller perform the diagnostic process when the control apparatus receives operational input for starting the diagnostic process.

4. The wafer testing apparatus as claimed in claim 1, wherein the diagnostic process is a process involving loading of a diagnostic board to the tester.

5. The wafer testing apparatus as claimed in claim 1, wherein the tester controller notifies the prober controller of a content of the diagnostic process upon receiving operational input for starting the diagnostic process.

6. The wafer testing apparatus as claimed in claim 5, wherein the prober controller notifies the tester controller that the diagnostic process is executable, when the tester has a diagnostic board loaded thereto corresponding to the content of the diagnostic process.

7. The wafer testing apparatus as claimed in claim 1, wherein upon the diagnostic process being performed, the tester controller notifies the prober controller of completion of the diagnostic process.

8. A wafer testing apparatus, comprising:
a tester configured to apply electrical signals to a semiconductor device fabricated on a wafer;
a prober configured to cause the semiconductor device to be electrically coupled to the tester;
a tester controller configured to control an operation of the tester; and
a prober controller configured to control an operation of the prober,
wherein the tester controller and the prober controller communicate with each other when exchanging probe cards for use in establishing electrical coupling between the semiconductor device and the tester.

9. A method of diagnosing a wafer testing apparatus which includes a tester to apply electrical signals to a semiconductor device fabricated on a wafer and a prober to cause the semiconductor device to be electrically coupled to the tester, the method comprising:
diagnosing a state of the tester by causing a tester controller for controlling an operation of the tester and a prober controller for controlling an operation of the prober to communicate with each other.
